(19) United States
(12) Patent Application Publication
(10) Pub. No.: US 2024/0310413 A1
(43) Pub. Date: Sep. 19, 2024

(54) CURRENT SHUNT USING WIRE BUNDLE CONSTRUCTION

(71) Applicant: Tektronix, Inc., Beaverton, OR (US)

(72) Inventors: Julie A. Campbell, Beaverton, OR (US); Daniel G. Knierim, Beaverton, OR (US); Matthew J. Hull, Beaverton, OR (US)

(21) Appl. No.: 18/604,102

(22) Filed: Mar. 13, 2024

Related U.S. Application Data
(60) Provisional application No. 63/453,025, filed on Mar. 17, 2023.

(51) Int. Cl. G01R 1/20; G01R 1/067

(52) U.S. Cl. CPC G01R 1/203; G01R 1/06794

(57) ABSTRACT

A test and measurement accessory includes a shunt configured to be located in a current path including a device under test, the shunt comprising a wire bundle of individually insulated wires as a resistive portion and a sense lead, the wire bundle and the sense lead electrically connected at a first end, a first electrical contact electrically connected to the sense lead at a second end, and a second electrical contact electrically connected to the wires of the wire bundle at the second end to allow measurement of a voltage drop across the first and second electrical contacts. A test and measurement system includes a test and measurement instrument and the test and measurement accessory. A method includes measuring current using the accessory.

### CROSS-REFERENCE TO RELATED APPLICATIONS

This disclosure is a non-provisional of and claims benefit from U.S. Provisional Application No. 63/453,025, titled “CURRENT SHUNT USING LITZ WIRE CONSTRUCTION,” filed on Mar. 17, 2023, the disclosure of which is incorporated herein by reference in its entirety.

### TECHNICAL FIELD

This disclosure relates to test and measurement instruments, and more particularly to a current shunt to be used with a test and measurement instrument to measure electrical current.

### BACKGROUND

Large and rapidly changing currents, such as are common in switching power supplies and motor drives using Wide Band Gap (WBG) semiconductors, and in lightning or other arc discharges, are notoriously difficult to measure accurately.

One approach often used is to place a series resistor (“current shunt resistor,” “current shunt,” or “shunt”) in the current path, measure the voltage drop caused by the current, and divide by the resistance. This approach handles DC and lower frequencies well, but suffers at higher frequencies due to the inductive drop across the shunt, which exceeds the resistive drop for frequencies above a frequency fc:

$$V = R \cdot i + L \cdot \frac{di}{dt}$$

$${f}_{c} = \frac{R}{2 π \cdot L}$$

When measuring large currents, a relatively small shunt resistance R is needed to keep the voltage drop and power dissipation of the shunt within reason, which leads to objectionably low usable bandwidth f_{c}.

The inductive drop can be eliminated by using a coaxial shunt, in which the resistive element is a cylinder, the return current passes through a larger and concentric outer cylinder, and the voltage measurement leads are routed out from the shunt inside the resistive cylinder. The symmetrical nature and the outer return current path ensure the magnetic field generated by the current circles between the shunt and the outer return path, leaving no magnetic field to impart an inductive drop on the measured voltage inside the shunt. Coaxial shunts eliminate measurement inductance, inductance included in the measured voltage drop, but require a longer current path through the shunt, thus increasing the insertion inductance, inductance inserted in the current path of the device under test (DUT). Even with no measurement inductance, coaxial shunts have limited bandwidth due to the skin effect of the shunt material. As frequency increases, the skin depth of electric current in a conductor decreases. Once the skin depth approaches the thickness of the resistive cylinder, a significantly lower portion of the current flows on the inside of the shunt, generating less resistive drop on the inside where the voltage is measured.

Another method to improve the usable bandwidth of a shunt is to add a canceling mutual inductance M_{C} in the lead dress of the voltage measurement leads of a conventional shunt:

$$V = R \cdot i + L \cdot \frac{di}{dt} - {M}_{C} \cdot \frac{di}{dt}$$

This minimizes the insertion inductance by not requiring a particular return current path but is trickier to implement because the return current path must still be known to determine lead placement to achieve cancelation (M_{C}=L). The cancellation approach also suffers at high frequency due to skin effect: the current path through the shunt will shift in physical location as the skin depth approaches the shunt thickness, changing M_{C}, L, & R.

### BRIEF DESCRIPTION OF THE DRAWINGS

FIG. 1 shows a test and measurement instrument, a device under test (DUT) and a test accessory having a shunt.

FIG. 2 shows an example of woven wire.

FIG. 3 shows an embodiment of a shunt.

FIG. 4 shows another embodiment of a shunt.

FIG. 5 shows an embodiment of a woven wire having a crimped end.

FIGS. 6-7 show embodiments of a current shunt having a dedicated sense lead.

FIGS. 8-9 show embodiments of a current shunt having a sense lead selected from a woven wire.

### DETAILED DESCRIPTION

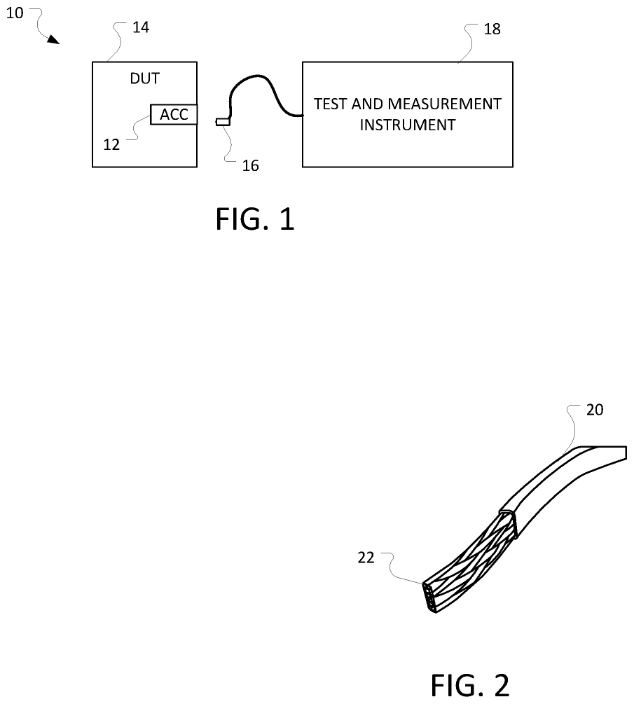

The embodiments here provide a test accessory for use with test and measurement instruments. The accessory includes a current shunt, or shunt, to allow measurement of a voltage across the shunt, but minimizes the skin-effect-induced change in shunt resistance with frequency. The shunt is located in a current path for the DUT. In some embodiments, as shown in FIG. 1, the test and measurement system 10 will have the accessory 12 soldered or otherwise connected directly to the device under test (DUT) 14. A probe, probes, or connector(s) 16 from the test and measurement instrument 18 will connect to the shunt to measure the voltage drop across the shunt. The test and measurement instrument will then convert the voltage to current by dividing by the resistance.

Wire bundles, such as litz wire, are often used to minimize the skin effect loss in RF wiring, inductors, and transformers. As used herein, and shown in FIG. 2, the term “wire bundle” refers to a bundle 20 of individually insulated wire strands, such as 22, twisted, woven, or braided. The individual strands have a diameter small enough to minimize the skin effect of the individual strand. The twist, weave, or braid serves to ensure each strand sees the same average magnetic field, and therefore carries the same portion of the total current. Litz wire comprises one example of this type of wire bundle. Litz wire is generally built with copper or silver-plated copper strands, as the intent is to minimize resistive losses. Practical strand sizes, for example 48 AWG, limit the usefulness of copper litz wire to several MHz.

Embodiments include a shunt constructed using a wire bundle to minimize the skin-effect-induced change in shunt resistance with frequency. The wire bundle forms the resistive portion of the shunt. The wire bundle may comprise wire strands of manganin, nichrome, or other suitable resistive metal alloy with minimal temperature coefficient of resistance and intentionally higher bulk resistivity than copper. The higher bulk resistivity leads to a proportionally higher frequency of operation for a given skin depth, allowing such a shunt to avoid skin effect up to 100 MHz or more. The range of the temperature coefficient of resistance may comprise a range of less than or equal to half that of copper, which is 0.0039/° C., making the range 0.00195/° C. or lower. The range of the bulk resistivity may comprise a range of more than or equal to twice that of copper, which is 1.7×10⁻⁸ Ωm, making the range 3.4×10⁻⁸ Ωm or higher.

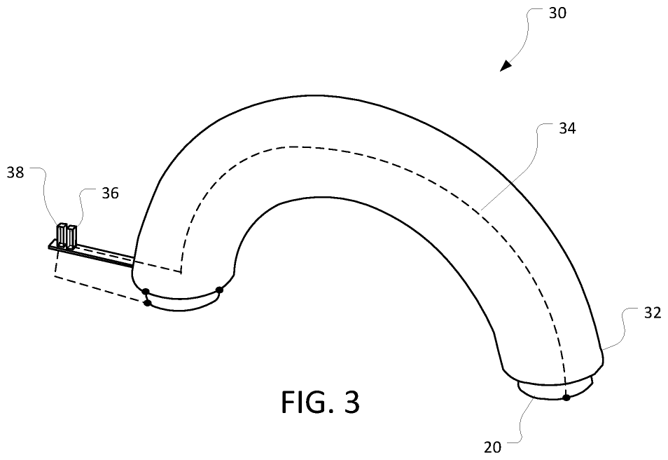

FIG. 3 shows an embodiment in which the shunt 30 comprises a wire bundle such as 20 shown in FIG. 2, wound, twisted, braided, or woven around a central sense wire 34 and placed inside a conductive tube 32, with the wire bundle electrically connected to the sense wire at one end, the near end as shown in the drawing, and the conductive tube at the other end. This forms a coaxial shunt, avoiding the inductive drop, while also minimizing the bandwidth loss due to skin effect. The sense lead 34 connects to a first electrical contact 36, in this embodiment a pin of a connector. The wire bundle at the far end would connect to the second pin 38. The voltage drop can then be measured between the first and second pin. The electrical contacts for all embodiments may take many different forms, such as pins, contact pads, traces, direct solder connections, etc.

According to another example embodiment of the disclosure, a shunt is constructed that retains the central sense wire from the example above but eliminates the coaxial current return path to allow more flexibility in placing the shunt in the DUT current path so as to minimize insertion inductance. This provides nominally cancelling mutual inductance and minimizes the skin-effect-induced change in M_{C}, L, & R with frequency.

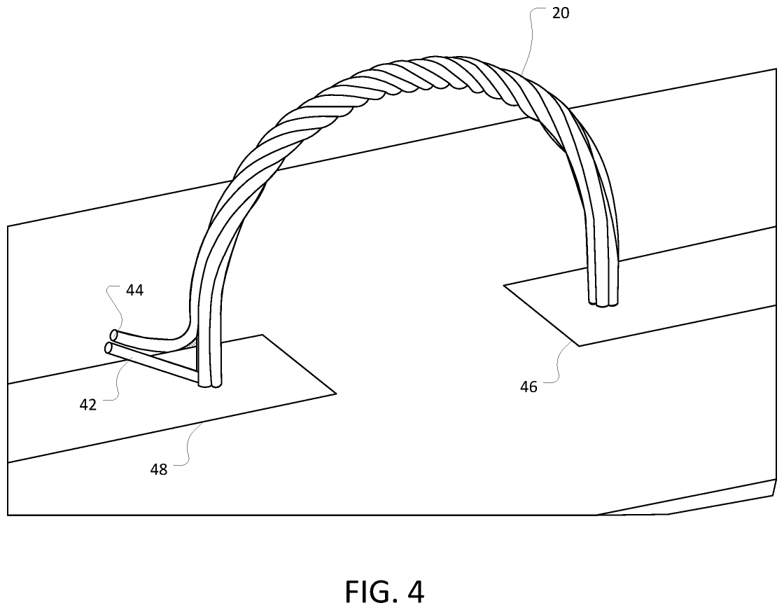

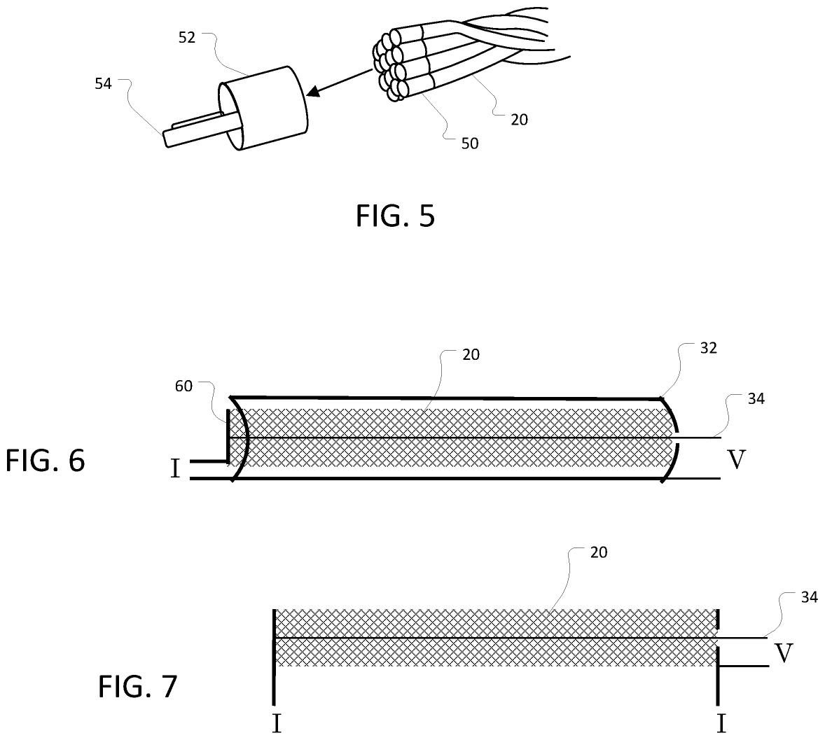

FIG. 4 shows another embodiment in which the sense wire 44 comprises one of the individual strands of the wire bundle. Since the wire bundle endeavors to make each of the strands see the same net magnetic field along the length of wire, any strand should provide the appropriate cancelling mutual inductance for any/all other strands. This approach may be easier to implement, as there is no need to identify the sense wire at each end. All strands are electrically connected at one end at current path segment 46. One strand 44 is selected and brought out separately as a sense lead at the other end of the wire bundle. Strand 44 does not contact the current path segment 48. All the other strands of the wire bundle besides strand 44 are electrically connected together at current path segment 48. Another lead 42 can be provided and connected to current path segment 48 so that the voltage drop across the wire bundle 20 can be conveniently measured by measuring the voltage difference between leads 42 and 44. Lead 44 may connect to a first electrical contact, and lead 42 may connect to a second electrical contact. In some embodiments, the first and second electrical contacts comprise the two pins of the square pin connector shown in FIG. 3, for example. In some embodiments, of any variations discussed herein, the ends of wire bundle 20 may be crimped. FIG. 5 shows an example of the wires being crimped together. In some embodiments, the ends of the wire bundle 20 may also have connectors, for example to connect to current path segments 46, 48. The electrical contacts and/or current segments for all embodiments may take many different forms, such as pins, contact pads, traces, direct solder connections, power planes, vias to trace, etc.

FIG. 5 shows the wire bundle 20 crimped together. The wires in the wire bundle will have their individual insulative sleeves stripped back to expose a portion of each wire as a bare wire 50. The bare wires then slide into the crimp 52. The crimp 52 has pins such as 54 to allow the bundle to be attached to the substrate. In addition, the bare wire ends may also be soldered together at one or both ends, with the exception of the sense lead at the second end.

The embodiments discussed here include four variations, either with or without the coaxial return path, and either with a separate, dedicated sense lead, or with a sense lead selected from the wire strands of the wire bundle. FIGS. 6-7 show a current path and voltage sense diagram for the embodiments having a separate sense lead, 34. In FIG. 6, current enters on the left, connects to all strands of the wire bundle at 60, travels down the wire bundle shunt 20, and then returns through the outer conductive tube 32. The sense wire 34 travels down the center of the wire bundle 20, forming a coaxial shunt. Note that the wire bundle is connected to the sense wire and the current input side of the figure on the left and to the conductive tube on the right. The letter “I” designates the current connections, and the letter “V” designates the voltage sense lead connections in FIGS. 6-9.

FIG. 7 shows an embodiment with the central sense lead 34 but no conductive tube. The embodiment allows or requires the user to provide the current return path. This may be advantageous if the DUT already needed a section of wire to conduct current. The wire bundle shunt can now replace that section of wire without adding any additional current path length. This embodiment may lose the pure symmetry of a coaxial shunt, but the wire bundle construction should still insure a uniform current density surrounding the sense lead, minimizing any inductive pick-up.

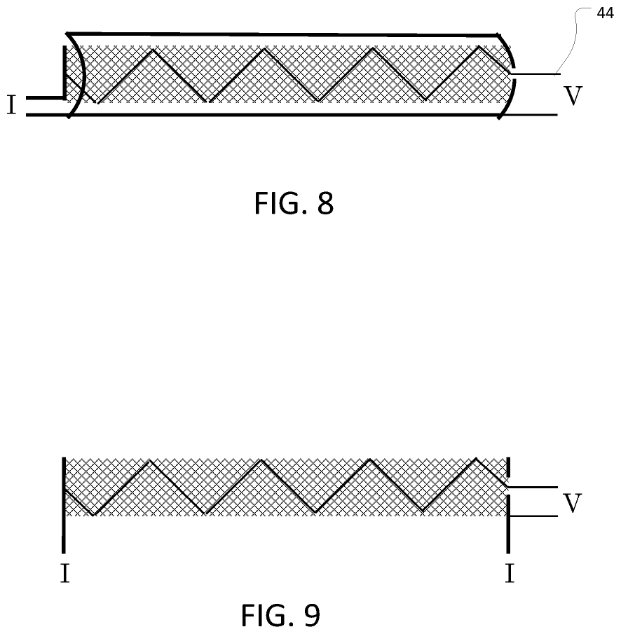

FIGS. 8-9 show embodiments where one of the wire strands of the wire bundle acts as the sense lead. In these figures, the sense lead 44 corresponds to the selected one or more of the wire strands from the wire bundle 20, with the remaining, un-selected wires of the bundle carrying the current. As the sense lead is one of the twisted, braided, or woven strands of wire, it may follow many different patterns/directions along the wire bundle. The current path travels from the left side of the figures in whatever path the bundle forms as it twists, loops, etc., to the other end of the shunt. In FIG. 8, the current returns along the conductive tube. In FIG. 9, the current will return along a path provided by the user.

One should note that any of these embodiments, as well as others not shown, may involve a bend or arc in the wire bundle. The wire bundle is inherently very flexible due to its stranded nature with a large number of strands. For example, the wire might make a 180° loop to solder into a pair of through-holes on a PCB as shown in FIGS. 3 and 4. It might make a 90° bend to route from a PCB through-hole to a solder lug destined to be fastened onto a terminal strip. No limitation to any particular shape or form of the wire bundle is intended, nor should any be inferred.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable infor mation. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is test and measurement accessory, comprising: a shunt configured to be located in a current path including a device under test, the shunt comprising a wire bundle of individually insulated wires as a resistive portion and a sense lead, the wire bundle and the sense lead electrically connected at a first end; a first electrical contact electrically connected to the sense lead at a second end; and a second electrical contact electrically connected to the wires of the wire bundle at the second end to allow measurement of a voltage drop across the first and second electrical contacts.

Example 2 is the test and measurement accessory of Example 1, wherein the sense lead is separate from the wire bundle, the wire bundle surrounding the sense lead.

Example 3 is the test and measurement accessory of either of Examples 1 or 2, wherein the sense lead comprises one or more wires from the wire bundle.

Example 4 is the test and measurement accessory of any of Examples 1 through 3, wherein the wire bundle is one of braided, woven, or twisted.

Example 5 is the test and measurement accessory of any of Examples 1 through 4, wherein the wire bundle comprises a litz wire.

Example 6 is the test and measurement accessory of any of Examples 1 through 5, wherein the wire bundle and sense lead are encased in a conductive tube, and the wire bundle is connected to the conductive tube at the second end.

Example 7 is the test and measurement accessory of any of Examples 1 through 6, wherein the first and second electrical contacts comprise one of contact pads, directly soldered, or part of a connector.

Example 8 is the test and measurement accessory of any of Examples 1 through 7, wherein the individually insulated wires of the wire bundle comprise a resistive metal alloy having at least one of a temperature coefficient of resistance of less than or equal to one half the temperature coefficient of resistance of copper, and a bulk resistivity of more than or equal to twice the bulk resistivity of copper.

Example 9 is the test and measurement accessory of Example 8, wherein the individually insulated wires of the wire bundle comprise a resistive metal alloy comprised of one of a copper alloy, manganin, or nichrome.

Example 10 is the test and measurement accessory of any of Examples 1 through 9, wherein at least one of the first and second ends comprises one or more of a connector, a crimp, and have the wires in the wire bundle soldered together.

Example 11 is a test and measurement system, comprising: a test and measurement instrument having a probe to connect to a device under test; and a test and measurement accessory, comprising: a shunt configured to be located in a current path including a device under test, the shunt comprising a wire bundle of individually insulated wires as a resistive portion and a sense lead, the wire bundle and the sense lead electrically connected at a first end; a first electrical contact electrically connected to the sense lead at a second end; and a second electrical contact electrically connected to the wires of the wire bundle at the second end to allow measurement of a voltage drop across the first and second electrical contacts.

Example 12 the test and measurement system of Example 11, wherein the first electrical contact and the second electrical contact reside on a connector configured to connect to the probe.

Example 13 the test and measurement system of either of Examples 11 or 12, wherein the sense lead is separate from the wire bundle, the wire bundle surrounding the sense lead.

Example 14 the test and measurement accessory of any of Examples 11 through 13, wherein the sense lead comprises one or more wires from the wire bundle.

Example 15 the test and measurement system of any of Examples 11 through 14, wherein the shunt is configured to be connected to a board upon which the device under test resides, and the first and second electrical contacts reside on the board.

Example 16 the test and measurement system of any of Examples 11 through 15, wherein the shunt further comprises a conductive tube encasing the wire bundle and the sense lead, the wire bundle connected to the conductive tube at the second end.

Example 17 the test and measurement system of any of Examples 11 through 16 wherein at least one of the first and second ends of the wire bundle comprises one or more of a connector, a crimp, and have the wires in the wire bundle soldered together.

Example 18 is method of measuring a current in a device under test (DUT), comprising: electrically connecting a test accessory in a current path of the DUT, the test accessory comprising a shunt, the shunt comprising a wire bundle of individually insulated wires as a resistive portion and a sense lead, the wire bundle and the sense lead electrically connected at a first end, a first electrical contact electrically connected to the sense lead at a second end, and a second electrical contact electrically connected to the wires of the wire bundle at the second end to allow measurement of a voltage drop across the first and second electrical contacts; and determining the current in the device under test by measuring the voltage difference between the first and second electrical contacts.

Example 19 is the method of measuring a current of Example 18, wherein electrically connecting the test accessory comprises providing a conductive tube to encase the wire bundle and the sense lead to provide a co-axial return path.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific examples of the invention have been illustrated and described for purposes of illustration, it will be understood that various modifications may be made without departing from the spirit and scope of the invention. Accordingly, the invention should not be limited except as by the appended claims.

1. A test and measurement accessory, comprising:
a shunt configured to be located in a current path including a device under test, the shunt comprising a wire bundle of individually insulated wires as a resistive portion and a sense lead, the wire bundle and the sense lead electrically connected at a first end;
a first electrical contact electrically connected to the sense lead at a second end; and
a second electrical contact electrically connected to the wires of the wire bundle at the second end to allow measurement of a voltage drop across the first and second electrical contacts.

2. The test and measurement accessory as claimed in claim 1, wherein the sense lead is separate from the wire bundle, the wire bundle surrounding the sense lead.

3. The test and measurement accessory as claimed in claim 1, wherein the sense lead comprises one or more wires from the wire bundle.

4. The test and measurement accessory as claimed in claim 1, wherein the wire bundle is one of braided, woven, or twisted.

5. The test and measurement accessory as claimed in claim 1, wherein the wire bundle comprises a litz wire.

6. The test and measurement accessory as claimed in claim 1, wherein the wire bundle and sense lead are encased in a conductive tube, and the wire bundle is connected to the conductive tube at the second end.

7. The test and measurement accessory as claimed in claim 1, wherein the first and second electrical contacts comprise one of contact pads, directly soldered, or part of a connector.

8. The test and measurement accessory as claimed in claim 1, wherein the individually insulated wires of the wire bundle comprise a resistive metal alloy having at least one of a temperature coefficient of resistance of less than or equal to one half the temperature coefficient of resistance of copper, and a bulk resistivity of more than or equal to twice the bulk resistivity of copper.

9. The test and measurement accessory as claimed in claim 8, wherein the individually insulated wires of the wire bundle comprise a resistive metal alloy comprised of one of a copper alloy, manganin, or nichrome.

10. The test and measurement accessory as claimed in claim 1, wherein at least one of the first and second ends comprises one or more of a connector, a crimp, and have the wires in the wire bundle soldered together.

11. A test and measurement system, comprising:
a test and measurement instrument having a probe to connect to a device under test; and
a test and measurement accessory, comprising:
a shunt configured to be located in a current path including a device under test, the shunt comprising a wire bundle of individually insulated wires as a resistive portion and a sense lead, the wire bundle and the sense lead electrically connected at a first end;
a first electrical contact electrically connected to the sense lead at a second end; and
a second electrical contact electrically connected to the wires of the wire bundle at the second end to allow measurement of a voltage drop across the first and second electrical contacts.

12. The test and measurement system as claimed in claim 11, wherein the first electrical contact and the second electrical contact reside on a connector configured to connect to the probe.

13. The test and measurement system as claimed in claim 11, wherein the sense lead is separate from the wire bundle, the wire bundle surrounding the sense lead.

14. The test and measurement accessory as claimed in claim 11, wherein the sense lead comprises one or more wires from the wire bundle.

15. The test and measurement system as claimed in claim 11, wherein the shunt is configured to be connected to a board upon which the device under test resides, and the first and second electrical contacts reside on the board.

16. The test and measurement system as claimed in claim 11, wherein the shunt further comprises a conductive tube encasing the wire bundle and the sense lead, the wire bundle connected to the conductive tube at the second end.

17. The test and measurement system as claimed in claim 11, wherein at least one of the first and second ends of the wire bundle comprises one or more of a connector, a crimp, and have the wires in the wire bundle soldered together.

18. A method of measuring a current in a device under test (DUT), comprising:
electrically connecting a test accessory in a current path of the DUT, the test accessory comprising a shunt, the shunt comprising a wire bundle of individually insulated wires as a resistive portion and a sense lead, the wire bundle and the sense lead electrically connected at a first end, a first electrical contact electrically connected to the sense lead at a second end, and a second electrical contact electrically connected to the wires of the wire bundle at the second end to allow measurement of a voltage drop across the first and second electrical contacts; and
determining the current in the device under test by measuring the voltage difference between the first and second electrical contacts.

19. The method of measuring a current as claimed in claim 18, wherein electrically connecting the test accessory comprises providing a conductive tube to encase the wire bundle and the sense lead to provide a co-axial return path.
